(19) United States
(12) Patent Application Publication
(10) Pub. No.: US 2015/0361557 A1
(43) Pub. Date: Dec. 17, 2015

(54) SUBSTRATE PROCESSING APPARATUS AND SUBSTRATE PROCESSING METHOD

(71) Applicant: ASM IP Holding B.V., Almere (NL)

(72) Inventor: Shintaro UEDA, Tokyo (JP)

(73) Assignee: ASM IP Holding B.V., Almere (NL)

(21) Appl. No.: 14/306,593

(22) Filed: Jun. 17, 2014

(51) Int. Cl. C23C 16/48; C23C 16/455; C23C 16/44

(52) U.S. Cl. CPC C23C 16/482; C23C 16/4412; C23C 16/45561

(57) ABSTRACT

A substrate processing apparatus includes a susceptor on which a substrate is placed, a processing chamber that accommodates the susceptor, a multi-wavelength light source that generates multi-wavelength light, a light absorption chamber partially comprising a transmission plate for allowing the multi-wavelength light to pass therethrough and configured to prevent a gas from accessing the processing chamber, an introducing pipe that introduces the gas into the light absorption chamber, and an exhaust pipe that exhausts the gas from the light absorption chamber, wherein the multi-wavelength light passes through the transmission plate, then passes through the light absorption chamber and reaches the substrate.

### BACKGROUND OF THE INVENTION

1. Field of the Invention

The present invention relates to a substrate processing apparatus and a substrate processing method used to reform a film formed on a substrate.

2. Background Art

A film such as an insulating film formed on a substrate may be irradiated with light to reform the film. Light emitted from a light source having a plurality of emission lines (multi- wavelength light) is used as the light to be radiated onto the film. In order to reform the film and obtain a desired film characteristic, a light source that emits light of a desired wavelength is selected from among a variety of light sources. For example, Japanese Patent Application Laid-Open No. 2006-279083 discloses that a UV lamp is used as such a light source.

To irradiate the film with light and achieve desired film quality, it is necessary to know light of what wavelength and what degree of intensity should be radiated onto the film. This requires an ability to freely change the spectrum of light. However, there is no other choice but to change the light source to actually change the spectrum. For this reason, the spectrum can be changed only within a range of types of light source and it has been difficult to find an optimum spectrum to achieve desired film quality. In addition, there is a problem that changing the light source may cause deterioration to operating efficiency.

### SUMMARY OF THE INVENTION

The present invention has been implemented to solve the above-described problems and it is an object of the present invention to provide a substrate processing apparatus and a substrate processing method capable of changing a spectrum of light radiated onto a substrate without the need to change a light source.

The features and advantages of the present invention may be summarized as follows.

According to one aspect of the present invention, a substrate processing apparatus includes a susceptor on which a substrate is placed, a processing chamber that accommodates the susceptor, a multi-wavelength light source that generates multi-wavelength light, a light absorption chamber partially comprising a transmission plate for allowing the multi-wavelength light to pass therethrough and configured to prevent a gas from accessing the processing chamber, an introducing pipe that introduces the gas into the light absorption chamber, and an exhaust pipe that exhausts the gas from the light absorption chamber, wherein the multi-wavelength light passes through the transmission plate, then passes through the light absorption chamber and reaches the substrate.

According to another aspect of the present invention, a substrate processing method includes a gas introducing step of introducing a gas into a light absorption chamber, and an irradiation step of causing multi-wavelength light generated in a multi-wavelength light source to pass through the light absorption chamber, causing light of a specific wavelength of the multi-wavelength light to attenuate and then radiating the multi-wavelength light onto a substrate.

According to another aspect of the present invention, a substrate processing method, exhausting a gas from a light absorption chamber while introducing the gas into the light absorption chamber, causing the multi-wavelength light generated in the multi-wavelength light source to pass through the light absorption chamber with the gas flowing into the light absorption chamber, thereby causing light with a specific wavelength of the multi-wavelength light to attenuate and then radiating the multi-wavelength light onto a substrate. Other and further objects, features and advantages of the invention will appear more fully from the following description.

### BRIEF DESCRIPTION OF THE DRAWINGS

FIG. 1 is a diagram illustrating a substrate processing apparatus according to a first embodiment;

FIG. 2 illustrates wavelength dependency of a light absorption coefficient by gas type;

FIG. 3 is a diagram illustrating a spectrum of attenuated multi-wavelength light when an O₃ gas and inert gas are introduced into the light absorption chamber; and

FIG. 4 illustrates a difference FT-IR spectrum of the porous low dielectric film.

### DETAILED DESCRIPTION OF THE PREFERRED EMBODIMENTS

A substrate processing apparatus and a substrate processing method according to embodiments of the present invention will be described with reference to the accompanying drawings. The same or corresponding components will be assigned the same reference numerals and duplicate description may be omitted.

### First Embodiment

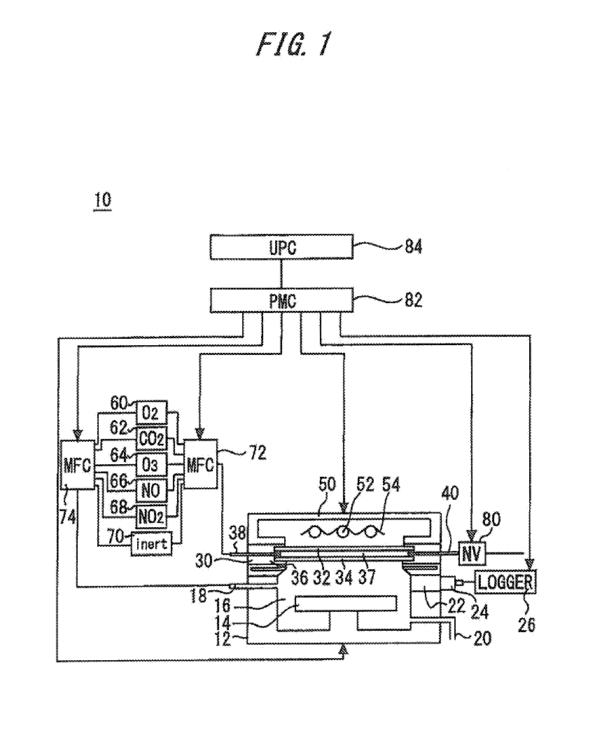

FIG. 1 is a diagram illustrating a substrate processing apparatus 10 according to a first embodiment of the present invention. The substrate processing apparatus 10 is provided with a processing chamber 12. The processing chamber 12 accommodates a susceptor 14 on which a substrate is placed. A region inside the processing chamber 12 is a processing space 16. An introducing pipe 18 that introduces a gas into the processing space 16 and an exhaust pipe 20 that exhausts the gas from the processing space 16 are connected to the processing chamber 12.

A view port 22 is provided in part of the processing chamber 12 so that the interior of the processing chamber 12 can be seen from outside the processing chamber 12. A spectrum acquiring section 24 is provided outside the processing chamber 12 to detect light inside the processing chamber 12 via the view port 22. The spectrum acquired by the spectrum acquiring section 24 is saved in a storage section 26 connected to the spectrum acquiring section 24.

A light absorption chamber 30 is attached to the processing chamber 12. The light absorption chamber 30 is configured so as to prevent a gas from accessing the processing chamber 12. The light absorption chamber 30 includes an upper transmission plate 32 and a lower transmission plate 34 provided apart from the upper transmission plate 32. The material of the upper transmission plate 32 and the lower transmission plate 34 is not particularly limited as long as it allows light to transmit therethrough, and can be, for example, crown glass or crystal.

The upper transmission plate 32 and the lower transmission plate 34 are fixed to a sidewall portion 36 formed so as to surround these plates in a plan view. The upper transmission plate 32, the lower transmission plate 34 and the sidewall portion 36 constitute the light absorption chamber 30. The space in the light absorption chamber 30 is called “light absorption space 37.” An introducing pipe 38 that introduces a gas into the light absorption chamber 30 and an exhaust pipe 40 that exhausts a gas from the light absorption chamber 30 are connected to the light absorption chamber 30.

A light source unit 50 is attached to the light absorption chamber 30. The light source unit 50 is provided with a multi-wavelength light source 52 that generates multi-wavelength light. The multi-wavelength light source 52 is composed of three xenon-based lamps that generate the same multi-wavelength light. A reflector 54 that directs the light emitted from the multi-wavelength light source 52 downward is provided on the multi-wavelength light source 52.

The substrate processing apparatus 10 is provided with an O₂ gas supply source 60, a CO₂ gas supply source 62, an O₃ gas supply source 64, an NO gas supply source 66, an NO₂ gas supply source 68 and an inert gas supply source 70. The plurality of gas supply sources are connected to the introducing pipe 38 via a mass flow controller 72 and also connected to the introducing pipe 18 via a mass flow controller 74. A plurality of gas supply sources are connected to the introducing pipes 38 and 18 in this way. For example, N2 gas, Ar gas or He gas is supplied from the inert gas supply source 70.

An exhaust amount control section 80 is connected to the exhaust pipe 40. The exhaust amount control section 80 is intended to control the exhaust amount from the light absorption chamber 30. The exhaust amount control section 80 is configured of, for example, a needle valve or an auto pressure controller.

The mass flow controllers 72 and 74, light source unit 50, exhaust amount control section 80, susceptor 14 and storage section 26 are connected to a PMC (process module controller) 82. Based on a command from a UPC (unique platform controller) 84 connected to the PMC 82, the PMC 82 controls the mass flow controllers 72 and 74, light source unit 50, exhaust amount control section 80, and susceptor 14 and also acquires data from the storage section 26.

Operation of the substrate processing apparatus 10 will be described. With the exhaust by the exhaust amount control section 80 disabled, a gas is introduced into the light absorption chamber 30 by controlling the mass flow controller 72. This step is called “ gas introducing step.” In the gas introducing step, a desired gas is introduced into the light absorption chamber 30 with desired volume concentration. Before moving to a step next to the gas introducing step, a substrate is placed on the susceptor 14 at appropriate timing

After the gas introducing step, power is supplied to the multi-wavelength light source 52 to generate multi-wavelength light. Multi-wavelength light before being introduced into the light absorption chamber 30 is called “initial multi-wavelength light.” The initial multi-wavelength light passes through the upper transmission plate 32, light absorption space 37 and lower transmission plate 34, and reaches the processing space 16. Light with a specific wavelength of the initial multi-wavelength light is absorbed by the gas in the light absorption chamber 30 (light absorption space 37). The multi-wavelength light that has reached the processing space 16 is called “attenuated multi-wavelength light.” Thus, multi-wavelength light is caused to pass through the light absorption chamber 30, light with a specific wavelength of the multi-wavelength light is caused to attenuate and then attenuated multi-wavelength light is radiated onto the substrate. This step is called a “radiation step.”

The spectrum of the multi-wavelength light (attenuated multi-wavelength light) after passing through the light absorption chamber 30 is acquired in the spectrum acquiring section 24 and stored in the storage section 26.

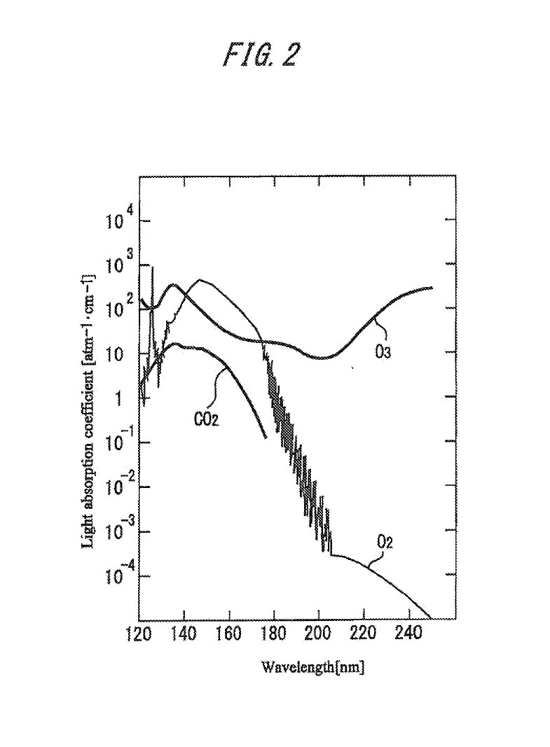

FIG. 2 illustrates wavelength dependency of a light absorption coefficient by gas type. It is clear from FIG. 2 that light of what wavelength is more likely to be absorbed. O₃ has a high absorption coefficient for light having a wavelength of 120 to 240 [nm]. Though not shown, O₃ also has a high absorption coefficient for light having the order of 240 to 300 [nm]. However, O₃ has quite a small absorption coefficient of, for example, 1×10⁻⁵ or less for light having a wavelength equal to or greater than 300 [nm].

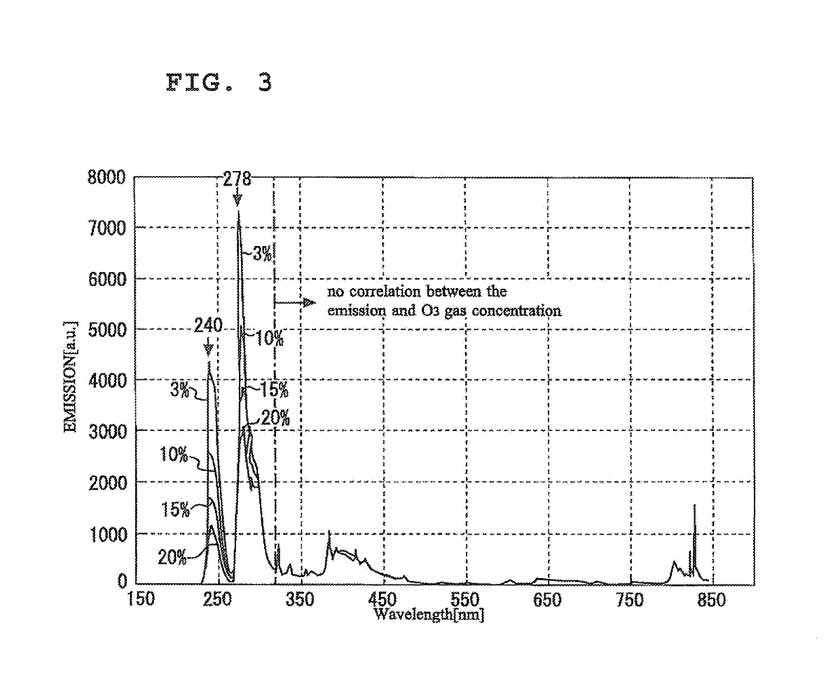

Therefore, when the O₃ gas is introduced into the light absorption space 37 and multi-wavelength light is made to pass therethrough, light having a wavelength of 120 to 300 [nm] attenuates, whereas light having a wavelength on the order of 300 [nm] does not attenuate. FIG. 3 is a diagram illustrating a spectrum (light intensity distribution) of attenuated multi-wavelength light when an O₃ gas and inert gas are introduced into the light absorption chamber 30. FIG. 3 shows four spectra. The first spectrum is marked “3%.” The first spectrum is a spectrum of the attenuated multi-wavelength light when an O₃ gas of 3% and an inert gas of 97% in volume concentration are introduced into the light absorption chamber 30. The second spectrum, third spectrum, and fourth spectrum are marked 10%, 15% and 20% respectively. The second spectrum is a spectrum of the attenuated multi-wavelength light when an O₃ gas of 10% and an inert gas of 90% in volume concentration are introduced into the light absorption chamber 30. The third spectrum is a spectrum of the attenuated multi-wavelength light when an O₃ gas of 15% and an inert gas of 85% in volume concentration are introduced into the light absorption chamber 30. The fourth spectrum is a spectrum of the attenuated multi-wavelength light when an O₃ gas of 20% and an inert gas of 80% in volume concentration are introduced into the light absorption chamber 30.

The initial multi-wavelength light emitted from the multi-wavelength light source 52 which is a xenon-based lamp has high light intensity at wavelengths of 240[nm] and 278[nm]. As is clear from FIG. 3, the light having wavelengths of 240[nm] and 278[nm] becomes more attenuated as the volume concentration of the O₃ gas in the light absorption chamber 30 increases. This is because the O₃ gas causes the light having a wavelength of 120 to 300[nm] to attenuate. On the other hand, light having a wavelength greater than the order of 300[nm] does not attenuate even when the volume concentration of the O₃ gas in the light absorption chamber 30 is increased. By introducing the O₃ gas into the light absorption chamber 30 in this way, it is possible to cause the light having a wavelength of 120 to 300[nm] to attenuate and cause the light having a wavelength greater than 300[nm] not to attenuate. Moreover, by changing the concentration of the O₃ gas, it is possible to control the amount of attenuated light. Therefore, it is possible to easily change the spectrum of light radiated onto the substrate without the need to change the light source.

The substrate processing apparatus 10 causes the gas in the light absorption chamber 30 to absorb light of a specific wavelength of the initial multi-wavelength light instead of radiating the initial multi-wavelength light directly onto the substrate, and can thereby radiate attenuated multi-wavelength light set to a desired spectrum onto the substrate. This feature allows reforming of the film which would not be possible by radiating the initial multi-wavelength light directly onto the substrate. That is, optimization of the spectrum of the attenuated multi-wavelength light makes it possible to freely reform the film such as increasing the mechanical strength of the film or decreasing the dielectric constant by introducing a porous film.

To obtain desired film quality, the spectrum of the attenuated multi-wavelength light must be optimized This optimization is experimentally performed using the substrate processing apparatus and the substrate processing method according to the first embodiment. More specifically, the type and concentration of the gas supplied into the light absorption chamber 30 are adjusted. One type or a plurality of types of gas may be supplied into the light absorption chamber 30. In addition, the concentration of the gas supplied into the light absorption chamber 30 may be adjusted by an inert gas or adjusted by a supply pressure of the gas. The experimenter compares the spectrum of the attenuated multi-wavelength light saved in the storage section 26 with the state of the film reformed by the attenuated multi-wavelength light, and thereby identifies the spectrum of the attenuated multi-wavelength light that can realize a desired film characteristic.

When the attenuated multi-wavelength light that can realize the desired film characteristic is found as a result of the experiment, the process moves to mass production of substrates. In the stage of mass production of substrates, the type and concentration of the gas supplied into the light absorption chamber 30 need not be changed on condition that the processing environment of the substrates does not change over time. However, due to the aging of, for example, the light absorption characteristic of the upper transmission plate 32 and the lower transmission plate 34, the desired attenuated multi-wavelength light may not be achieved. Thus, in the stage of mass production of substrates, data stored in the storage section 26 is fed back to the PMC 82 and a time variation of the spectrum of the attenuated multi-wavelength light is monitored. When the desired attenuated multi-wavelength light is not achieved, the PMC 82 adjusts the current flowing through the multi-wavelength light source 52 or adjusts the type and concentration of the gas supplied into the light absorption chamber 30 to thereby achieve the desired attenuated multi-wavelength light.

In the example of FIG. 3, the O₃ gas is introduced into the light absorption chamber 30, but another gas may be introduced into the light absorption chamber 30 to achieve the attenuated multi-wavelength light having the desired spectrum. The substrate processing apparatus 10 of the first embodiment of the present invention introduces at least one type of O₂ gas, CO₂ gas, O₃ gas, NO gas, and NO₂ gas into the light absorption chamber 30 in the gas introducing step. The type of the gas introduced into the light absorption chamber 30 is determined by the wavelength of light to be attenuated. For example, when light having a wavelength of 160[nm] is caused to selectively attenuate and light having a wavelength of 200[nm] is caused not to attenuate, a CO₂ gas may be introduced into the light absorption chamber 30. As shown in FIG. 2, the CO₂ gas has a high absorption coefficient for light having a wavelength from 120 to 170[nm]. Thus, by introducing the CO₂ gas into the light absorption chamber 30, it is possible to cause only light having a wavelength of 160[nm] out of the initial multi-wavelength light to attenuate and prevent the light having a wavelength of 200[nm] from attenuating.

According to FIG. 2, not only the CO₂ gas but also the O₂ gas has a high absorption coefficient for light having a wavelength around 160 [nm]. However, when the O₂ gas comes into contact with light having a wavelength below 240 [nm], the O₂ gas is converted into an O₃ gas. Therefore, after converting the O₂ gas to an O₃ gas with light having a wavelength below 240 [nm], if an irradiation step is executed, a result shown in FIG. 3 is obtained.

By controlling the mass flow controller 74, it is possible to introduce any given gas into the processing chamber 12 in accordance with processing contents of the substrate. The gas introduced into the processing chamber 12 is combined with the film of the substrate and reforms the film. Moreover, since the light absorption chamber 30 is configured so as not to allow the gas to access the processing chamber 12, it is possible to prevent the gas in the light absorption chamber 30 from reacting with the substrate of the processing space 16. The light absorption chamber 30 is preferably detachably attached to the processing chamber 12. When degradation of the upper transmission plate 32 and the lower transmission plate 34 advances to an extent that absorption of multi-wavelength light by these plates becomes no longer negligible, the detachable attachment of the light absorption chamber 30 allows the light absorption chamber 30 itself to be replaced or allows the upper transmission plate 32 and the lower transmission plate 34 to be replaced.

A vacuum pump may be connected to the exhaust pipe 20 to vacuum the processing space 16 and the irradiation step may be executed in that vacuum condition. A gas supply source other than the gas supply source shown in FIG. 1 may also be provided. The multi-wavelength light source 52 is not limited to a xenon-based lamp. A multi-wavelength light source best suited to contents of processing on the substrate may be selected. For example, a mercury lamp or fluorescent lamp may be used. If the upper transmission plate 32 and the lower transmission plate 34 cause the multi-wavelength light to attenuate, efficiency deteriorates, and so these plates should be made as thin as possible. When the processing space 16 is vacuumed, a support for controlling bending of the lower transmission plate 34 may be provided to prevent the lower transmission plate 34 from cracking due to the vacuum pressure.

The configuration of the light absorption chamber 30 is not limited to the configuration in FIG. 1. The light absorption chamber 30 is not particularly limited as long as it partially includes a transmission plate that allows multi-wavelength light to pass therethrough and prevent the gas from accessing the processing chamber 12. The shape of the transmission plate is not particularly limited as long as it allows the multi-wavelength light to pass through the transmission plate, pass through the light absorption chamber and reach the substrate.

Any kind of gases other than the N2 gas, Ar gas or He gas may be used as inert gas as long as such gas do not essentially affect initial multi-wavelength light.

These modifications are applicable to substrate processing apparatuses and substrate processing methods according to the following embodiments as appropriate. Note that the substrate processing apparatuses and substrate processing methods according to the following embodiments have many points common to the first embodiment, and therefore the following description will focus on differences from the first embodiment.

### Second Embodiment

According to a substrate processing method of a second embodiment, initial multi-wavelength light is introduced to the light absorption chamber 30 with the gas flowing into the light absorption chamber 30. That is, the gas is allowed to flow into the light absorption chamber 30 by controlling the mass flow controller 72 and the exhaust amount control section 80 to introduce the gas into the light absorption chamber 30 and at the same time exhaust the gas from the light absorption chamber 30. In this condition, the multi-wavelength light generated in the multi-wavelength light source 52 is caused to pass through the light absorption chamber 30, light having a specific wavelength of the multi-wavelength light is caused to attenuate and then radiated onto the substrate.

A specific example will be described. The mass flow controller 72 is controlled to introduce the O₂ gas from the introducing pipe 38 into the light absorption chamber 30, and the exhaust amount control section 80 is controlled to exhaust the O₂ gas from the exhaust pipe 40. In this way, the O₂ gas is caused to flow into the light absorption space 37. In this condition, the initial multi-wavelength light is caused to pass through the light absorption chamber 30. The initial multi-wavelength light has emission lines at wavelengths of 172 [nm], 190 [nm], 240 [nm], 278 [nm], and 370 [nm]. A porous low dielectric constant film is formed on the substrate. This porous low dielectric constant film is irradiated with attenuated multi-wavelength light. This processing is cure processing that reforms the surface condition of the porous low dielectric constant film.

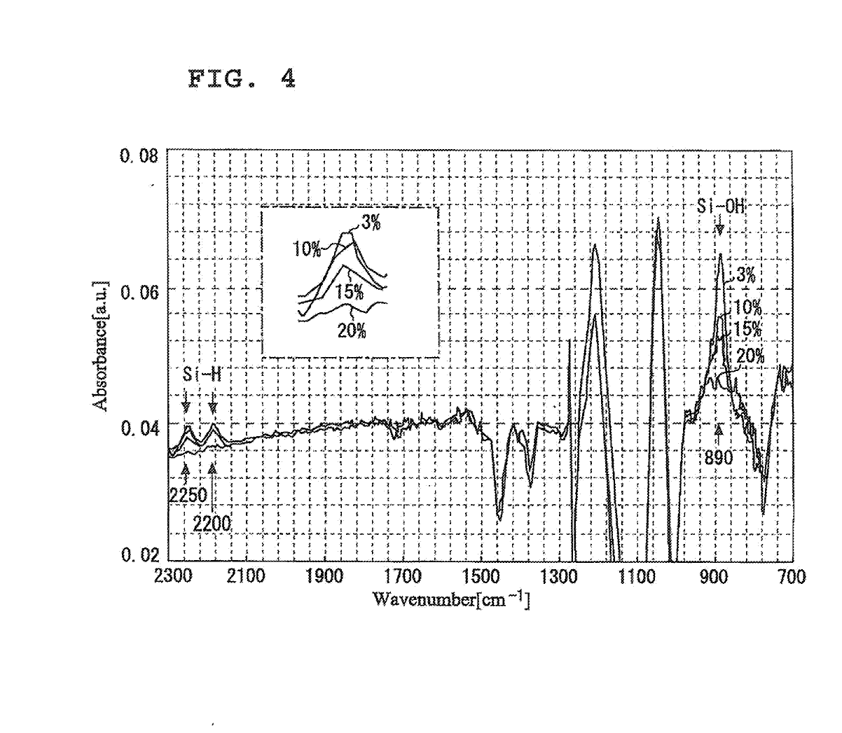

FIG. 4 illustrates a difference FT-IR spectra of the porous low dielectric film. This difference FT-IR spectra were obtained by subtracting FT-IR spectra taken after cure processing from FT-IR spectra taken before cure processing. FIG. 4 shows four FT-IR spectra. The first FT-IR spectrum is marked “3%.” The first FT-IR spectrum is a difference FT-IR spectrum of the porous low dielectric film when an O₂ gas of 3% and an inert gas of 97% in volume concentration are made to flow into the light absorption chamber 30.

The second FT-IR spectrum, third FT-IR spectrum and fourth FT-IR spectrum are marked 10%, 15% and 20% respectively. The second FT-IR spectrum is a difference FT-IR spectrum of the porous low dielectric film when an O₂ gas of 10% and an inert gas of 90% in volume concentration are made to flow into the light absorption chamber 30. The third FT-IR spectrum is a difference FT-IR spectrum of the porous low dielectric film when an O₂ gas of 15% and an inert gas of 85% in volume concentration are made to flow into the light absorption chamber 30. The fourth FT-IR spectrum is a difference FT-IR spectrum of the porous low dielectric film when an O₂ gas of 20% and an inert gas of 80% in volume concentration are made to flow into the light absorption chamber 30. In all of the porous dielectric films of these four samples, the film thickness before irradiation with attenuated multi-wavelength light has been contracted by 20% through the irradiation with attenuated multi-wavelength light.

It is clear from FIG. 4 that Si—H bonds (2200 cm⁻¹, 2250 cm⁻¹) and Si—OH bonds (890 cm⁻¹) are formed by the irradiation with attenuated multi-wavelength light. Si—H bonds and Si—OH bonds are formed in the place where Si—O bonds were cut by light having a wavelength of 172 [nm]. Formation of Si—H bonds and Si—OH bonds take place with a heat supply from the susceptor 14.

As shown in FIG. 2, the O₂ gas has a higher absorption coefficient with respect to light having a wavelength on the order of 120 to 180 [nm] than the absorption coefficient with respect to light having other wavelengths. Therefore, the light having the wavelength of 172 [nm] is made to selectively attenuate by the O₂ gas out of initial multi-wavelength light having wavelengths of 172 [nm], 190 [nm], 240 [nm], 278 [nm], and 370 [nm]. Therefore, when the O₂ concentration in the light absorption chamber 30 is increased, the light of wavelength 172 [nm] particularly attenuates, causing the frequency with which the Si—O bonds are cut to decrease. For this reason, when the O₂ concentration in the light absorption chamber 30 is increased as shown in FIG. 4, the amount of generation of Si—H bonds and Si—OH bonds decreases. The area enclosed by a single-dot dashed line in FIG. 4 is an enlarged view of a spectrum around 2250 cm⁻¹.

Exhausting the gas from the light absorption chamber 30 while introducing the gas into the light absorption chamber 30 allows the gas in the light absorption chamber 30 to be always kept refreshed. For this reason, even when the O₂ gas is converted to an O₃ gas by receiving initial multi-wavelength light, the O₃ gas is immediately exhausted out of the light absorption space 37 and substantially only the O₂ gas is used for light absorption. Thus, the substrate processing method according to the second embodiment of the present invention is particularly effective when the gas in the light absorption chamber 30 is converted to another gas by initial multi-wavelength light and the gas before the conversion is desired to be used.

Desired attenuated multi-wavelength light may also be achieved using the nature that the gas in the light absorption chamber 30 is converted to another gas by the initial multi-wavelength light. For example, the exhausting speed may be slowed down by the exhaust amount control section 80 to create a condition in which the O₂ gas and O₃ gas coexist in the light absorption chamber 30.

Thus, it is possible to change the spectrum of light radiated onto the substrate without changing the light source by adjusting not only the type and concentration of the gas introduced into the light absorption chamber 30 but also the exhausting speed of the gas in the light absorption chamber.

According to the present invention, the gas in the light absorption chamber absorbs light of a specific wavelength, and therefore multi-wavelength light of a desired spectrum can be radiated on the substrate.

Obviously many modifications and variations of the present invention are possible in the light of the above teachings. It is therefore to be understood that within the scope of the appended claims the invention may be practiced otherwise than as specifically described.

What is claimed is:

1. A substrate processing apparatus comprising:
a susceptor on which a substrate is placed;
a processing chamber that accommodates the susceptor;
a multi-wavelength light source that generates multi-wavelength light;
a light absorption chamber partially comprising a transmission plate for allowing the multi-wavelength light to pass therethrough and configured to prevent a gas from accessing the processing chamber;
an introducing pipe that introduces the gas into the light absorption chamber; and
an exhaust pipe that exhausts the gas from the light absorption chamber,
wherein the multi-wavelength light passes through the transmission plate, then passes through the light absorption chamber and reaches the substrate.

2. The substrate processing apparatus according to claim 1, further comprising:
a plurality of gas supply sources connected to the introducing pipe; and
a mass flow controller provided between the plurality of gas supply sources and the introducing pipe.

3. The substrate processing apparatus according to claim 2, wherein the plurality of gas supply sources comprise an O₂ gas supply source, a CO₂ gas supply source, an O₃ gas supply source, an NO gas supply source, an NO₂ gas supply source, and an inert gas supply source.

4. The substrate processing apparatus according to claim 1, wherein the multi-wavelength light source is a mercury lamp, a fluorescent lamp or a xenon-based lamp.

5. The substrate processing apparatus according to claim 1, further comprising an exhaust amount control section connected to the exhaust pipe for controlling an amount of exhaust from the light absorption chamber.

6. The substrate processing apparatus according to claim 1, wherein the light absorption chamber is detachably attached to the processing chamber.

7. The substrate processing apparatus according to claim 1, further comprising:
a spectrum acquiring section that acquires a spectrum of the multi-wavelength light after passing through the light absorption chamber; and
a storage section that saves the spectrum acquired in the spectrum acquiring section.

8. A substrate processing method comprising:
a gas introducing step of introducing a gas into a light absorption chamber; and
an irradiation step of causing multi-wavelength light generated in a multi-wavelength light source to pass through the light absorption chamber, causing light of a specific wavelength of the multi-wavelength light to attenuate and then radiating the multi-wavelength light onto a substrate.

9. The substrate processing method according to claim 8,
wherein in the gas introducing step, at least one of a O₂ gas, a CO₂ gas, an O₃ gas, an NO gas and an NO₂ gas is introduced into the light absorption chamber, and
the multi-wavelength light source is a mercury lamp, fluorescent lamp or xenon-based lamp.

10. A substrate processing method, exhausting a gas from a light absorption chamber while introducing the gas into the light absorption chamber, causing the multi-wavelength light generated in the multi-wavelength light source to pass through the light absorption chamber with the gas flowing into the light absorption chamber, thereby causing light with a specific wavelength of the multi-wavelength light to attenuate and then radiating the multi-wavelength light onto a substrate.

11. The substrate processing method according to claim 10, wherein the gas includes an O₂ gas.
